(19) United States
(12) Patent Application Publication
(10) Pub. No.: US 2025/0256306 A1
(43) Pub. Date: Aug. 14, 2025

(54) CLEANING APPARATUS, ADJUSTMENT JIG, AND ADJUSTMENT METHOD

(71) Applicant: SHIBAURA MECHATRONICS CORPORATION, Yokohama-shi (JP)

(72) Inventors: Yuhei NEMOTO, Yokohama-shi (JP); Takahiro KANAI, Yokohama-shi (JP)

(73) Assignee: SHIBAURA MECHATRONICS CORPORATION, Yokohama-shi (JP)

(21) Appl. No.: 19/046,948

(22) Filed: Feb. 6, 2025

(30) Foreign Application Priority Data
Feb. 9, 2024 (JP) 2024-018600

(51) Int. Cl. B08B 1/52; B08B 1/12; B08B 1/20; B08B 1/36; B08B 3/04

(52) U.S. Cl. CPC B08B 1/52; B08B 1/12; B08B 1/20; B08B 1/36; B08B 3/04

(57) ABSTRACT

A cleaning apparatus includes: first and second dischargers configured to discharge a brush cleaning liquid so that the brush cleaning liquid lands linearly on contact surfaces of first and second brushes, in a state in which the first and second brushes configured to clean a substrate are located at a retracted position spaced apart from the substrate; and a support configured to support the first and second discharger, so that the brush cleaning liquid discharged from the first discharger and the brush cleaning liquid discharged from the second discharger do not interfere with each other until the brush cleaning liquid lands on the contact surfaces of the first and second brushes.

### CROSS-REFERENCE TO RELATED APPLICATION

This application is based upon and claims the benefit of priority from Japanese Patent Application No. 2024-018600, filed on Feb. 9, 2024, the entire contents of which are incorporated herein by reference.

### TECHNICAL FIELD

The present disclosure relates to a cleaning apparatus, an adjustment jig, and an adjustment method.

### BACKGROUND

A substrate processing apparatus is an apparatus used in a manufacturing process of a semiconductor, a liquid crystal panel, or the like to process a surface to be processed of a substrate (e.g., a wafer or a liquid crystal substrate) with a chemical solution, rinse the substrate with a rinsing liquid after the chemical solution processing, and dry the substrate after rinsing. In such a substrate processing apparatus, from a viewpoint of uniformity and reproducibility, a single-substrate method is used to process substrates sheet by sheet. In a single-substrate type substrate processing apparatus, a substrate is placed on a rotary table, and a processing liquid such as a chemical solution or the like is supplied to the substrate on the rotating rotary table, so that the substrate is processed with the processing liquid.

After the substrate processing process using the processing liquid, the substrate is cleaned by a substrate cleaning apparatus in order to maintain a high degree of cleanliness of the substrate. When performing multiple substrate processing processes using several types of processing liquids, the substrate may be cleaned by a substrate cleaning apparatus after each process in order to maintain the high degree of cleanliness of the substrate. As a substrate cleaning method using such a substrate cleaning apparatus, scrub cleaning with a brush is used. In the scrub cleaning, in a state of rotating a substrate, a brush is brought into contact with a surface of a substrate and moved horizontally to remove impurities (metals, organic materials, particles, and the like) on the substrate.

However, in a substrate cleaning apparatus using the above-mentioned scrub cleaning, impurities removed from the substrate may adhere to the brush and may contaminate a next substrate to be cleaned. Such contamination results in deterioration in quality of the substrate.

### SUMMARY

Some embodiments of the present disclosure provide a cleaning apparatus, an adjustment jig, and an adjustment method, which are capable of maintaining a degree of cleanliness of a brush for cleaning a substrate, and improving quality of a substrate.

A cleaning apparatus includes: a substrate cleaner configured to clean a first surface and a second surface of a substrate, which is being held and rotated, by bringing a circular contact surface of a rotating first brush into contact with the first surface of the rotating substrate while supplying a substrate cleaning liquid to the first surface of the rotating substrate, and by bringing a circular contact surface of a rotating second brush into contact with the second surface of the rotating substrate while supplying the substrate cleaning liquid to the second surface of the rotating substrate; and a brush cleaner configured to clean the first brush and the second brush by discharging a brush cleaning liquid from a discharger to the contact surface of the first brush and the contact surface of the second brush, in a state in which the first brush and the second brush are located at a retracted position spaced apart from a region where the substrate is held. The discharger includes: a first discharger configured to discharge the brush cleaning liquid so that the brush cleaning liquid lands linearly on the contact surface of the first brush; and a second discharger configured to discharge the brush cleaning liquid so that the brush cleaning liquid lands linearly on the contact surface of the second brush. The brush cleaner includes a support configured to support the first discharger and the second discharger, so that the brush cleaning liquid discharged from the first discharger and the brush cleaning liquid discharged from the second discharger do not interfere with each other until the brush cleaning liquid lands on the contact surface of the first brush and the contact surface of the second brush.

A cleaning apparatus includes: a substrate cleaner configured to clean one surface of a substrate, which is being held and rotated, by bringing a circular contact surface of a rotating brush into contact with the one surface of the rotating substrate while supplying a substrate cleaning liquid to the one surface of the substrate; a brush cleaner configured to clean the brush by discharging a brush cleaning liquid from a discharger to the contact surface, in a state in which the brush is located at a retracted position spaced apart from a region where the substrate is held; and a support configured to support the discharger. The support includes: a prismatic columnar fixing joint configured to support the discharger and having an internal flow path for supplying the brush cleaning liquid to the discharger; and a fixture including an insertion hole into which the fixing joint is inserted, the insertion hole having a plurality of surfaces brought into contact with a plurality of side surfaces of the fixing joint and being configured to fix an angle of the fixing joint.

An adjustment jig according to an embodiment is an adjustment jig for adjusting positions of a first discharger and a second discharger of a cleaning apparatus. The adjust jig includes: a liquid landing plate on which a brush cleaning liquid discharged from the first discharger and the second discharger lands at positions corresponding to contact surfaces of the first brush and the second brush; reference holes, which are a plurality of through-holes provided linearly and correspond to liquid landing areas, on which the brush cleaning liquid discharged from the first discharger and the brush cleaning liquid discharged from the second discharger land, respectively, in the liquid landing plate; and a fixer configured to selectively fix the liquid landing plate to any of a position corresponding to the contact surface of the first brush and a position corresponding to the contact surface of the second brush.

An adjustment method according to an embodiment is a method of adjusting positions of a first discharger and a second discharger of a cleaning apparatus by using an adjustment jig. The method includes: a first fixing process of fixing the liquid landing plate at a position corresponding to the contact surface of the first brush; after the first fixing process, a first liquid landing process of discharging the brush cleaning liquid from the first discharger so that the brush cleaning liquid lands on the liquid landing plate; a first adjustment process of adjusting the position of the first discharger based on a passing state of the brush cleaning liquid through the reference holes in the first liquid landing process; a second fixing process of fixing the liquid landing plate at a position corresponding to the contact surface of the second brush; after the second fixing process, a second liquid landing process of discharging the brush cleaning liquid from the second discharger so that the brush cleaning liquid lands on the liquid landing plate; and a second adjustment process of adjusting the position of the second discharger based on a passing state of the brush cleaning liquid through the reference holes in the second liquid landing process.

### BRIEF DESCRIPTION OF DRAWINGS

The accompanying drawings, which are incorporated in and constitute a part of the specification, illustrate embodiments of the present disclosure.

FIG. 1 is a transparent side view showing a schematic configuration of a cleaning apparatus according to an embodiment.

FIG. 2 is a plan view showing the schematic configuration of the cleaning apparatus according to the embodiment.

FIG. 3 is a front view showing a brush cleaner of the cleaning apparatus according to the embodiment.

FIG. 4 is a perspective view showing the brush cleaner and an adjustment jig.

FIGS. 5A and 5B are explanatory diagrams showing a discharge angle of a brush cleaning liquid by a discharger to a brush, wherein FIG. 5A is a view of the brush seen from a rear of a first discharger, and FIG. 5B is a view of the brush seen from a rear of a second discharger.

FIG. 6A is a plan view showing a liquid landing area on a first brush, and FIG. 6B is a plan view showing a liquid landing area on a second brush.

FIG. 7 is a perspective view showing a fixing joint.

FIG. 8A is a perspective view showing a first fixture, and FIG. 8B is a perspective view showing a second fixture.

FIG. 9 is a perspective view showing a state before the fixing joint supporting the first discharger is inserted into the first fixture.

FIG. 10 is a perspective view showing a state after the fixing joint supporting the first discharger is inserted into the first fixture.

FIG. 11 is a perspective view showing a state before the first fixture and the second fixture are attached to a holder.

FIG. 12 is a perspective view showing a state before the fixing joint supporting the second discharger is inserted into the second fixture.

FIG. 13 is a perspective view showing a state after the fixing joint supporting the second discharger is inserted into the second fixture.

FIG. 14 is a perspective view showing the first discharger having an angle determined by an angle determinator.

FIG. 15 is a horizontal cross-sectional view showing a cover.

FIG. 16 is a front view showing a base plate attached to a fixing plate.

FIG. 17A is a front view showing the adjustment jig, FIG. 17B is a plan view showing the adjustment jig, and FIG. 17C is a side view showing the adjustment jig.

FIG. 18A is an explanatory diagram showing checking discharge of the brush cleaning liquid from the first discharger by the adjustment jig, and FIG. 18B is an explanatory diagram showing checking discharge of the brush cleaning liquid from the second discharger by the adjustment jig.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

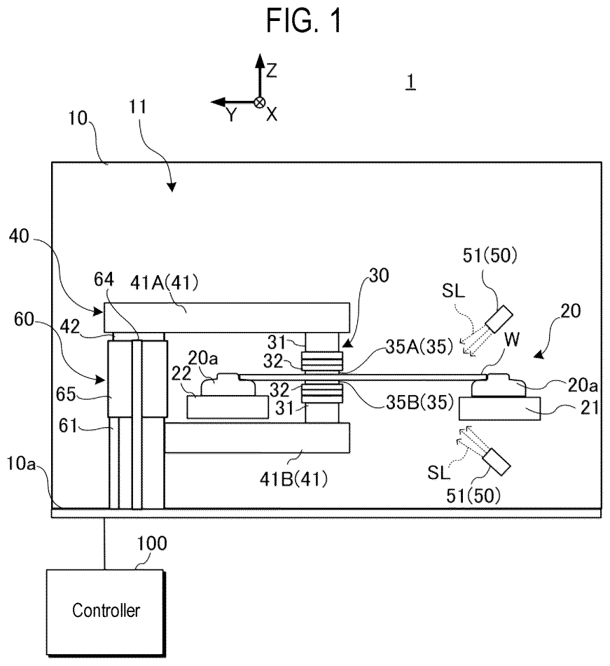

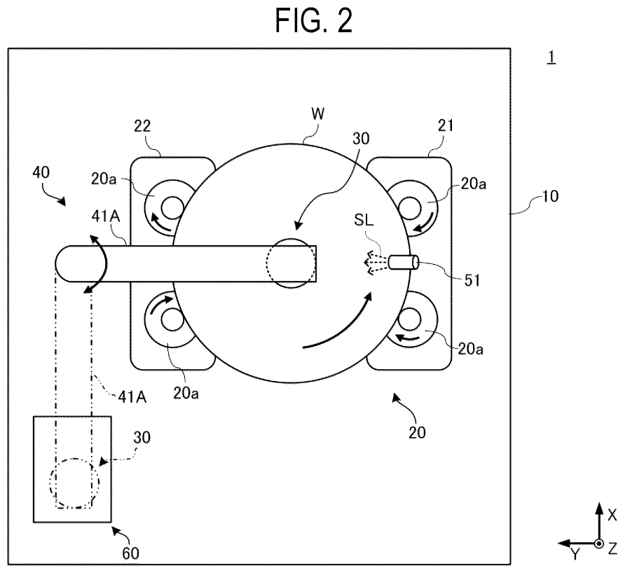

Hereinafter, an embodiment of the present disclosure will be described with reference to the drawings. As shown in FIGS. 1 and 2, the present embodiment is a cleaning apparatus 1 that cleans a substrate W with a substrate cleaning liquid SL and a brush 35 while rotating the substrate W. The substrate W to be cleaned is typically a semiconductor wafer, but may also be a substrate for a display device, and the like.

The substrate W has a disk shape. In the following description, an upper surface and a lower surface of the substrate W are referred to as a front surface (first surface) and a back surface (second surface), respectively, and when referring to both the front surface and the back surface, they are referred to as front and back surfaces of the substrate W. In addition, an outer peripheral end surface is a side surface other than the front and back surfaces of the substrate W. In addition, in FIG. 1, a vertical direction is referred to as a Z direction, and among horizontal directions perpendicular to the Z direction, a left-right direction as viewed from a front (a right-hand side in FIG. 1) is referred to as an X direction, and a front-rear direction perpendicular to the X direction is referred to as a Y direction.

### Configuration

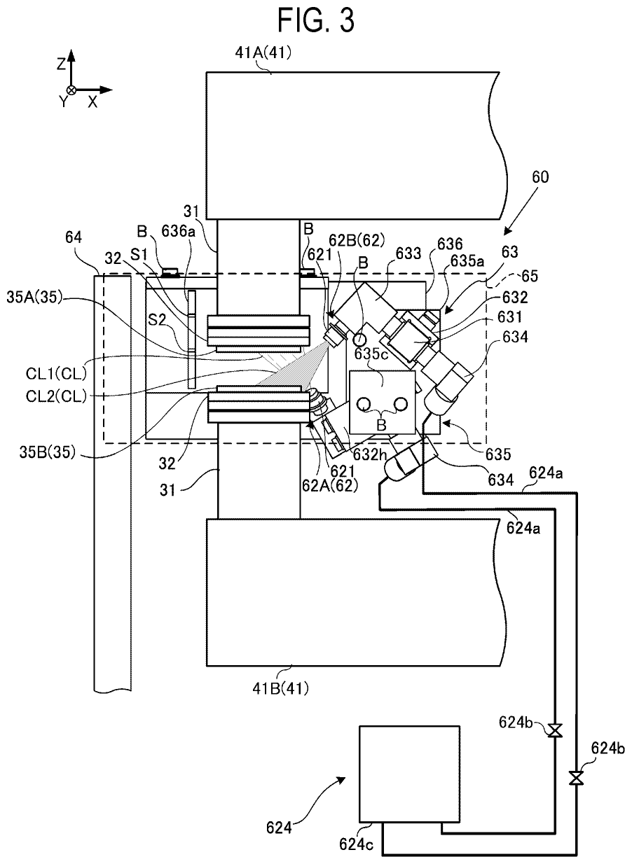

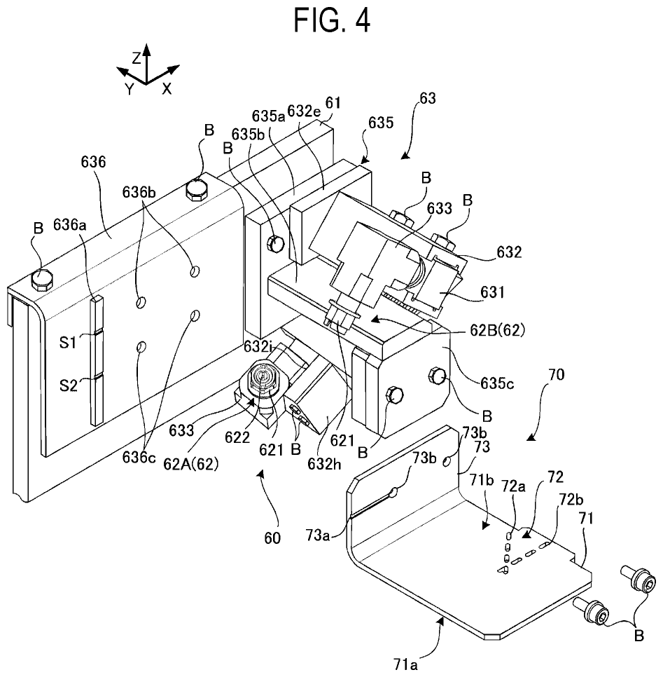

As shown in FIGS. 1 and 2, the cleaning apparatus 1 includes a chamber 10, a rotation driver 20, a substrate cleaner 30, a brush driver 40, a cleaning liquid discharger 50, a brush cleaner 60, and a controller 100. In addition, an adjustment jig 70 is used to adjust positions of a first discharger 62A and a second discharger 62B in the brush cleaner 60 (see FIG. 4). FIG. 1 is a transparent view showing an interior of the chamber 10, and FIG. 2 is a plan view of the interior of the chamber 10. In addition, an enlarged view of the brush cleaner 60 is shown in FIG. 3.

### Chamber

The chamber 10 is a container having a cleaning chamber 11 for cleaning the substrate W loaded thereinto. The chamber 10 is a rectangular parallelepiped housing, and an internal space thereof serves as the cleaning chamber 11. In addition, a bottom of the chamber 10 is indicated by reference numeral 10a. Although not shown, a load/unload port for loading and unloading the substrate W by a transfer robot is provided on one side surface of the chamber 10, and a work port for a maintenance work is provided on the other side surface. Each of the load/unload port and the work port is configured to be opened and closed by a door, which is driven by an opening/closing mechanism. In addition, although not shown, a drainage port is formed at the bottom 10a of the chamber 10. A substrate cleaning liquid and a brush cleaning liquid that fall on the bottom 10a of the chamber 10 are discharged to outside of the cleaning apparatus 1 via the drainage port.

### Rotation Driver

As shown in FIG. 2, the rotation driver 20 rotationally drives the substrate W by rotating a plurality of rollers 20a that holds an outer periphery of the substrate W. As shown in FIG. 1, the rotation driver 20 includes a first holder 21 and a second holder 22. The first holder 21 and the second holder 22 are disposed at positions that face each other in the left-right direction in FIG. 2 with respect to a center of the substrate W.

Each of the first holder 21 and the second holder 22 includes a pair of rollers 20a. The rollers 20a are provided to be rotatable about an axis perpendicular to a direction in which the surface of the substrate W extends. Each roller 20a includes a cylindrical large diameter portion having a large diameter, and a cylindrical small diameter portion having a small diameter and provided coaxially with the large diameter portion. The rollers 20a hold the substrate W by bring side surfaces of the small diameter portions into contact with the outer periphery of the substrate W. The rollers 20a are formed of a material having a resistance to the substrate cleaning liquid SL, such as PEEK or the like.

A rotation mechanism such as a motor or the like for rotating the rollers 20a is accommodated inside each of the first holder 21 and the second holder 22. The first holder 21 and the second holder 22 are configured so that the rollers 20a can move to be in contact with or separated from the substrate W by a drive mechanism (not shown). As the first holder 21 and the second holder 22 move to be spaced apart from each other by the drive mechanism, the rollers 20a are located at release positions at which the rollers 20a are spaced apart from the substrate W. In addition, as the first holder 21 and the second holder 22 are moved toward each other by the drive mechanism, the rollers 20a are located at holding positions at which the rollers 20a are in contact with and hold the substrate W.

### Substrate Cleaner

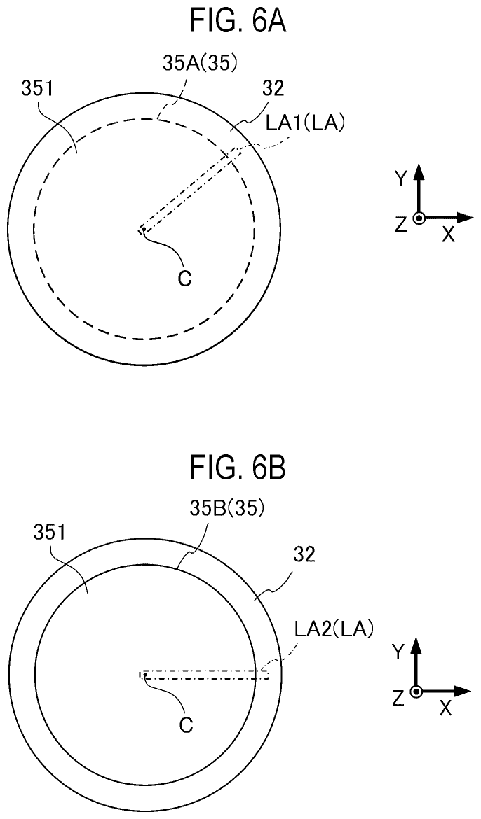

The substrate cleaner 30 includes brushes 35 that clean the surface of the substrate W by being rotated and brought into contact with the surface of the rotating substrate W. The brushes 35 include a first brush 35A and a second brush 35B. Each of the first brush 35A and the second brush 35B has a contact surface 351 that is brought into contact with the substrate W. The first brush 35A and the second brush 35B are cylindrical, and the contact surface 351 is circular (see FIGS. 6A and 6B). The first brush 35A and the second brush 35B are provided on the same axis and are disposed one above the other so that the contact surfaces 351 thereof face each other.

When it is not necessary to distinguish the first brush 35A and the second brush 35B from each other, they are simply referred to as the brush 35. In addition, the contact between the brush 35 and the surface of the substrate W includes both a case where the contact surface 351 of the brush 35 is in direct contact with the substrate W and a case where the contact surface 351 is in contact with the substrate W via the substrate cleaning liquid SL. The brush 35 is made of a material having flexibility and elasticity.

The brush 35 uses a spongy-like resin such as PVA (nylon-based resin), PTFE (fluorine-based resin), or the like. Alternatively, a bristle brush made of the same resin may be used. That is, the brush 35 may be a brush using a sponge-like mass, or may be a brush using densely packed bristles. The brush 35 may use, as the spongy-like mass, a mass of densely packed fibrous bodies. In such a case, the contact surface 351, which is not strictly flat, is brought into contact with the substrate W.

As shown in FIG. 1, the brush 35 is detachably attached to a support provided on a cylindrical body 31 via a brush holder 32. A motor (not shown) as a drive source for rotating the brush 35 is built in the body 31.

### Brush Driver

The brush driver 40 moves the substrate cleaner 30 in a direction parallel to the surface of the substrate W. As shown in FIG. 1, the brush driver 40 includes an arm 41 and a drive mechanism 42. The arm 41 is a member that extends in the direction parallel to the substrate W, and has one end to which the substrate cleaner 30 is attached. A first arm 41A supports the first brush 35A, and a second arm 41B supports the second brush 35B. When it is not necessary to distinguish the first arm 41A and the second arm 41B from each other, they are simply referred to as the arm 41. The drive mechanism 42 includes a swing mechanism and a lift mechanism.

As shown in FIG. 2, the swing mechanism reciprocates the arm 41 in parallel to the substrate W, from a position above the outer periphery of the substrate W to a position above the outer periphery on an opposite side, along an arc trajectory with an end portion of the arm 41 opposite to the substrate cleaner 30 as an axis. In addition, the swing mechanism reciprocates the arm 41 to move from a retracted position outside a region in which the substrate W is held to a position above the outer periphery of the substrate W. In FIG. 2, the first arm 41A and the substrate cleaner 30 when the brush 35 is located at the retracted position are indicated by two-dot chain lines. As will be described later, the retracted position is also a brush cleaning position where the brush 35 is cleaned by the brush cleaner 60. The swing mechanism includes a support shaft extending from the other end of the arm 41 in a direction perpendicular to a surface direction of the substrate W, and a motor (not shown) as a drive source for swinging the support shaft. The arm 41 is positioned so that the brush 35 is located at the retracted position when the cleaning of the substrate W is not performed.

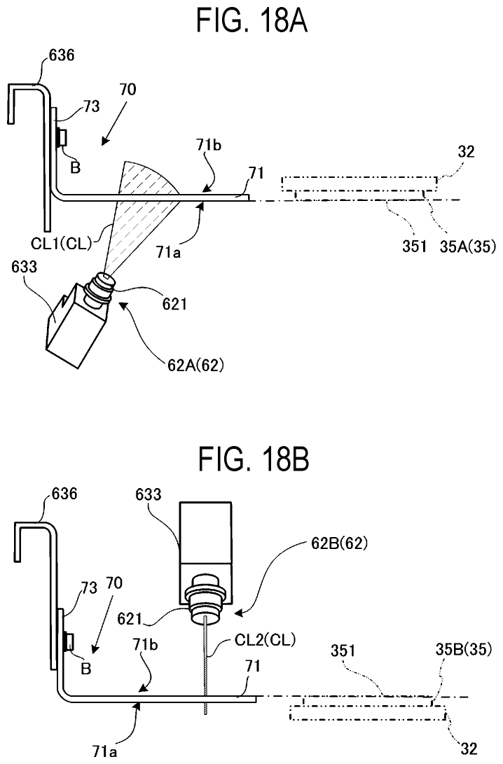

The lift mechanism moves the arm 41 so that the substrate cleaner 30 is in contact with or separated from the substrate W. As the lift mechanism, a ball screw mechanism, a cylinder, or the like that moves the support shaft of the arm 41 vertically may be used. As shown in FIG. 3, the lift mechanism of the present embodiment moves the arm 41 vertically so that the contact surface 351 of the first brush 35A and the contact surface 351 of the second brush 35B are spaced apart from each other when the brush 35 is at the retracted position. More specifically, the lift mechanism moves the first arm 41A vertically so that a position of the contact surface 351 of the first brush 35A becomes a position of a first liquid landing surface 71a of the adjustment jig 70 when the adjustment jig 70 described later is attached (see FIG. 18A). In addition, the lift mechanism moves the second arm 41B vertically so that a position of the contact surface 351 of the second brush 35B becomes a position of a second liquid landing surface 71b of the adjustment jig 70 when the adjustment jig 70 described later is attached (see FIG. 18B).

### Cleaning Liquid Discharger

The cleaning liquid discharger 50 discharges the substrate cleaning liquid SL to the substrate W. The cleaning liquid discharger 50 discharges the substrate cleaning liquid SL from a nozzle 51 toward both surfaces of the rotating substrate W. The substrate cleaning liquid SL in the present embodiment is ozone water, pure water, or SC-1 (a cleaning liquid made by mixing ammonia water and hydrogen peroxide water). The cleaning liquid discharger 50 is connected to a supply mechanism for the substrate cleaning liquid SL (not shown) via a pipe. The supply mechanism includes a liquid sending device, valves, and the like connected to a pure water production device (pure water storage tank), an ozone water production device (ozone water storage tank), and an SC-1 supply device, and can supply any of pure water, ozone water, and SC-1 in a switched manner.

The substrate cleaner 30, the brush driver 40, and the cleaning liquid discharger 50 as described above are provided in pair vertically with the substrate W interposed therebetween so that the front and back surfaces of the substrate W can be cleaned. That is, the first arm 41A and the second arm 41B of the brush driver 40 are disposed above and below the substrate W, respectively, so that the contact surface 351 of each of the pair of the first brush 35A and the second brush 35B faces the substrate W. The drive mechanism 42 moves the first arm 41A and the second arm 41B between a contact position where the first brush 35A and the second brush 35B are in contact with the substrate W with the substrate W interposed therebetween, and a separation position where the first brush 35A and the second brush 35B are spaced apart from the substrate W.

Further, the drive mechanism 42 swings the first arm 41A and the second arm 41B to move the first brush 35A and the second brush 35B located at the contact position along an arc trajectory. Furthermore, the first brush 35A and the second brush 35B are cleaned by the brush cleaner 60 described later at the retracted position out of the substrate W.

### Brush Cleaner

As shown in FIG. 3, the brush cleaner 60 cleans the first brush 35A and the second brush 35B with a brush cleaning liquid CL in a state in which the first brush 35A and the second brush 35B are located at the retracted position. In addition, in the following description, a cleaning liquid discharged by the first discharger 62A is referred to as a brush cleaning liquid CL1, and a cleaning liquid discharged by the second discharger 62B is referred to as a brush cleaning liquid CL2. When it is not necessary to distinguish the brush cleaning liquid CL1 and the brush cleaning liquid CL2 from each other, they are referred to as a brush cleaning liquid CL. The brush cleaner 60 includes a fixing plate 61, a discharger 62, a support 63, a support column 64, and a cover 65.

### <Fixing Plate>

The fixing plate 61 is a plate that extends vertically upward from the bottom 10a of the chamber 10 as shown in FIGS. 1 and 4.

### <Discharger>

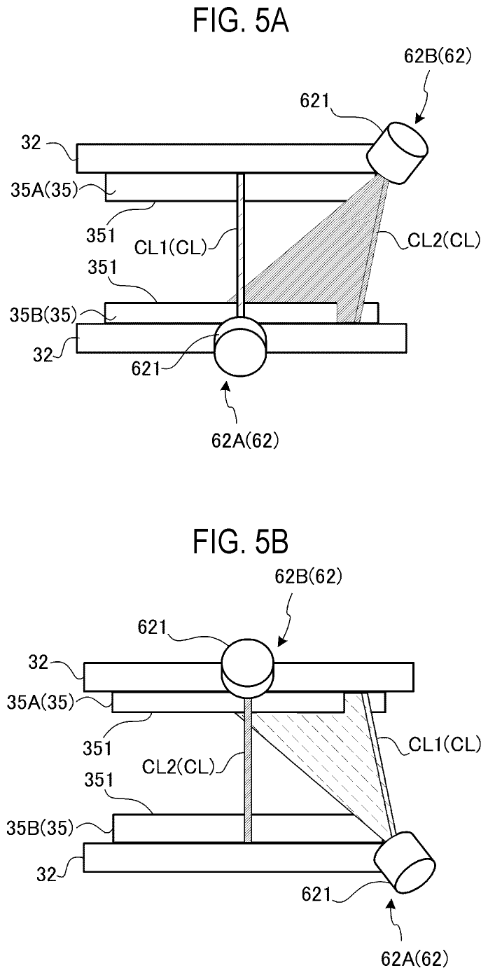

As shown in FIGS. 4 to 5B, the discharger 62 discharges the brush cleaning liquid CL to the contact surfaces 351 to clean the first brush 35A and the second brush 35B. The discharger 62 includes the first discharger 62A and the second discharger 62B. The first discharger 62A discharges the brush cleaning liquid CL1 so that the brush cleaning liquid CL1 lands linearly on the contact surface 351 of the first brush 35A as shown in FIG. 6A. This liquid landing area is referred to as LA1. The second discharger 62B discharges the brush cleaning liquid CL2 so that the brush cleaning liquid CL2 lands linearly on the contact surface 351 of the second brush 35B as shown in FIG. 6B. This liquid landing area is referred to as LA2. In the surface direction of the contact surfaces 351 of the first brush 35A and the second brush 35B, a direction in which the liquid landing area LA1 extends linearly is different from a direction in which the liquid landing area LA2 extends linearly. The first discharger 62A and the second discharger 62B discharge the brush cleaning liquid CL from outside the first brush 35A and the second brush 35B so that a discharge direction (a direction in which an axis of a nozzle tip 621 of the discharger 62 described later extends) is oblique with respect to the contact surface 351. For example, the brush cleaning liquid CL may be discharged so that the discharge direction is 35 degrees to 45 degrees with respect to the contact surface 351. Hereinafter, when the first discharger 62A and the second discharger 62B are not distinguished from each other, they are simply referred to as the discharger 62. In addition, when the liquid landing areas LA1 and LA2 are not distinguished from each other, they are simply referred to as the liquid landing area LA.

The discharger 62 has the cylindrical nozzle tip 621. That is, the discharger 62 in the present embodiment is a so-called nozzle that discharges the brush cleaning liquid CL. An elliptical discharge port 622 is formed at a front end of the nozzle tip 621. Thus, as shown in FIGS. 3, 5A, and 5B, the brush cleaning liquid CL discharged from the discharge port 622 is spread in a fan-like planar shape from the discharge port 622, and as shown in FIGS. 6A and 6B, forms the linear liquid landing area LA along a major axis direction of the discharge port 622 on the contact surface 351 of the brush 35. Spreading the brush cleaning liquid CL in a fan-like planar shape means that a cross section of a spray pattern of the discharged brush cleaning liquid CL is spread in a flat shape. In addition, the liquid landing area LA may be formed in an elongated ellipse. That is, the discharger 62 (nozzle tip 621) may be one that causes the liquid landing area LA to be a spray pattern of an elongated ellipse. As such, the term “linear” also includes a case in which there is a bulge in a width direction perpendicular to a longitudinal direction of the liquid landing area LA. A thread groove is cut on an outer periphery of a rear end of the nozzle tip 621, and the nozzle tip 621 is screw-fixed to an end portion of a discharger-side joint 633 described later. By changing an amount of screwing the nozzle tip 621, it is possible to change an angle of the discharge port 622 about the axis of the nozzle tip 621 to adjust an angle of the liquid landing area LA on the contact surface 351.

### <Support>

The support 63 supports the first discharger 62A and the second discharger 62B. As shown in FIG. 3, the first discharger 62A and the second discharger 62B supported by the support 63 are disposed in a region between the first arm 41A and the second arm 41B when the brush 35 is positioned at the retracted position.

Further, the first discharger 62A and the second discharger 62B supported by the support 63 are positioned so that the brush cleaning liquids CL1 and CL2 discharged from the first discharger 62A and the second discharger 62B, respectively, do not interfere with each other. In other words, the support 63 supports the first discharger 62A and the second discharger 62B so that the brush cleaning liquids CL1 and CL2 discharged in a fan-like planar shape from the first discharger 62A and the second discharger 62B do not collide with each other before landing on the contact surfaces 351.

Furthermore, as shown in FIGS. 6A and 6B, the linear liquid landing area LA where the brush cleaning liquid CL discharged from the discharger 62 lands on the contact surface 351 of the brush 35 has a length that covers from an outer peripheral edge to a center C of the contact surface 351. Moreover, as shown in FIGS. 5A and 5B, a plane of the brush cleaning liquid CL, which is formed by the brush cleaning liquid CL discharged from the discharger 62 and spread in a planar shape until the brush cleaning liquid CL lands on the contact surface 351 of the brush 35, is perpendicular to the contact surface 351.

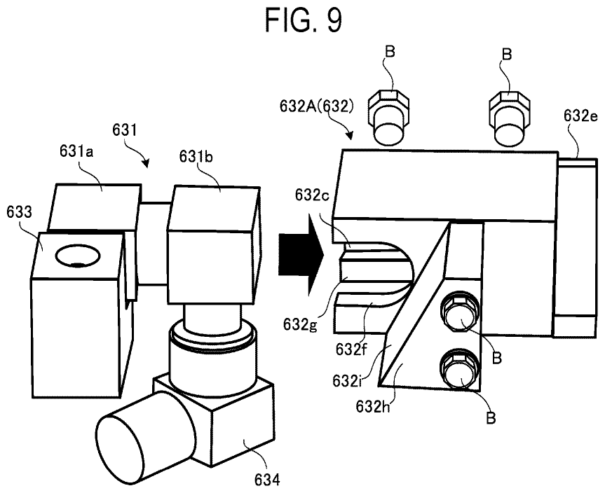

As shown in FIG. 4, the support 63 includes a fixing joint 631, a fixture 632, a discharger-side joint 633, a supply-side joint 634 (see FIG. 9), a holder 635, and a base plate 636.

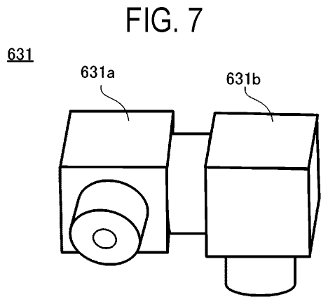

As shown in FIGS. 3, 4, 7, and 9, the fixing joint 631 supports the discharger 62, has an internal flow path for supplying the brush cleaning liquid CL to the discharger 62, and has corners on an outer periphery thereof. In the present embodiment, the fixing joint 631 supports the discharger 62 via the discharger-side joint 633, which will be described later. The fixing joint 631 has a prismatic columnar shape. As shown in FIG. 7, the fixing joint 631 of the present embodiment includes rectangular parallelepiped blocks 631a and 631b. The blocks 631a and 631b are rotatably connected to each other.

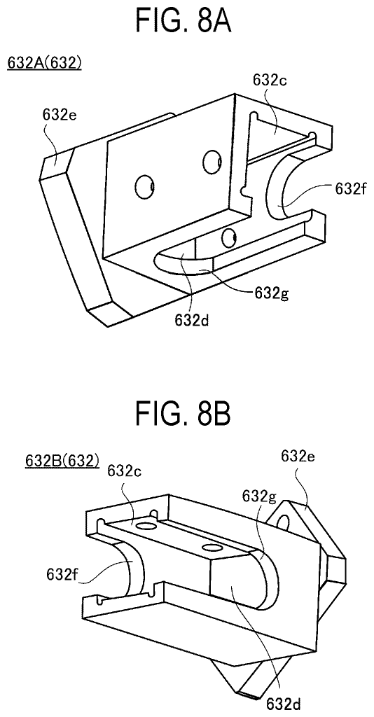

As shown in FIGS. 8A and 8B, the fixture 632 has an insertion hole 632c that receives the fixing joint 631, has a plurality of surfaces with which a plurality of side surfaces of the fixing joint 631 is in contact, and fixes an angle of the fixing joint 631. The insertion hole 632c also has a contact surface 632d that is brought into contact with an end of the fixing joint 631 to determine a position of the fixing joint 631 in an insertion direction. The fixture 632 of the present embodiment is a cylindrical body having a rectangular parallelepiped shape. One end of the insertion hole 632c is open, and the other end is closed by the contact surface 632d. Since the fixing joint 631 and the insertion hole 632c have a rectangular parallelepiped shape, by bringing four surfaces of the fixing joint 631 and four surfaces of the insertion hole 632c into contact with each other, an angle about an axis parallel to the insertion direction of the fixing joint 631 is fixed. In addition, an attachment plate 632e is fixed to an end portion of the fixture 632 on a side of the contact surface 632d.

More specifically, as shown in FIG. 9, by inserting the blocks 631a and 631b of the fixing joint 631 rotatably connected to each other into the insertion hole 632c, four surfaces of the blocks 631a and 631b are brought into contact with the four surfaces of the insertion hole 632c, so that rotation thereof about an axis is restricted. The fixing joint 631 inserted into the insertion hole 632c is fixed by fasteners B such as bolts or the like via a hole provided in the fixture 632, so that movement thereof in the insertion direction is restricted.

As shown in FIGS. 8A and 8B, a discharger groove 632f into which a connection portion between the below-described discharger-side joint 633 and the fixing joint 631 is inserted from an open end portion, and a supply groove 632g into which a connection portion between the supply-side joint 634 and the fixing joint 631 is inserted from an open end portion, are formed in side surfaces of the fixture 632. The discharger groove 632f and the supply groove 632g have different lengths in the insertion direction. In other words, the supply groove 632g is a groove deeper than the discharger groove 632f.

Here, the fixture 632 into which the fixing joint 631 supporting the first discharger 62A is inserted is referred to as a first fixture 632A, and the fixture 632 into which the fixing joint 631 supporting the second discharger 62B is inserted is referred to as a second fixture 632B. As shown in FIG. 8A, the discharger groove 632f and the supply groove 632g of the first fixture 632A are formed in two adjacent side surfaces. As shown in FIG. 8B, the discharger groove 632f and the supply groove 632g of the second fixture 632B are formed in two opposing side surfaces.

As shown in FIGS. 3, 9, and 10, the discharger-side joint 633 has an internal flow path for supplying the brush cleaning liquid CL to the discharger 62, and is connected to the fixing joint 631 so that an angle of the discharger 62 fixed to the discharger-side joint 633 can be changed. The discharger-side joint 633 of the present embodiment is an L-shaped block. As described above, the nozzle tip 621 is screw-inserted to one end of the discharger-side joint 633 (see FIG. 3). The other end of the discharger-side joint 633 is connected to the fixing joint 631.

When the fixing joint 631 is inserted into the insertion hole 632c of the fixture 632, and the connection portion between the discharger-side joint 633 and the fixing joint 631 is inserted into the discharger groove 632f. As a result, the discharger-side joint 633 is supported to protrude from one side surface of the fixture 632.

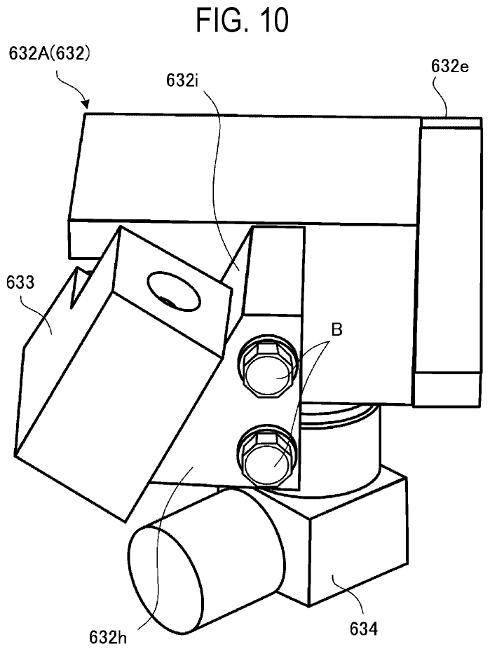

In addition, as shown in FIG. 10, the first fixture 632A corresponding to the first discharger 62A is provided with an angle determinator 632h, which is in contact with the discharger-side joint 633 and determines an angle of the discharger 62. The angle determinator 632h has an inclined surface 632i, and the inclined surface 632i is in contact a side surface of the discharger-side joint 633 to determine an angle of the discharger-side joint 633.

As shown in FIGS. 3, 9, and 10, the supply-side joint 634 is connected to the fixing joint 631, a flow path for supplying the brush cleaning liquid CL to the discharger 62 is formed in the supply-side joint 634, and a pipe 624a for supplying the brush cleaning liquid CL is connected to the supply-side joint 634. In the present embodiment, the supply-side joint 634 is an L-shaped block. As shown in FIG. 3, one end of the supply-side joint 634 is connected to the fixing joint 631, and the other end thereof is connected to a liquid supply 624. The liquid supply 624 includes the pipe 624a and a valve 624b, which are connected to the other end of the supply-side joint 634, and a supply device 624c for the brush cleaning liquid CL connected to the pipe 624a. For example, pure water is used as the brush cleaning liquid CL. Further, the supply device 624c may be the same as the cleaning liquid discharger 50. Furthermore, a part of the supply mechanism, such as a supply source of the brush cleaning liquid CL or the like, may be common to the cleaning liquid discharger 50.

When the fixing joint 631 is inserted into the insertion hole 632c of the fixture 632, the connection portion between the supply-side joint 634 and the fixing joint 631 is inserted into the supply groove 632g. As a result, the supply-side joint 634 is supported in the fixture 632 to protrude from one side surface different from the surface from which the discharger-side joint 633 protrudes.

The discharger 62 and the supply-side joint 634 are provided at positions spaced apart from each other in the insertion direction of the fixing joint 631 into the fixture 632. More specifically, the discharger-side joint 633 and the supply-side joint 634 are connected to different blocks 631a and 631b of the fixing joint 631, and the discharger groove 632f and the supply groove 632g provided in the fixture 632 of the fixing joint 631 have different lengths. As a result, positions of the discharger 62 and the supply-side joint 634 deviate from each other in the insertion direction.

In addition, a protruding direction of the discharger-side joint 633 and a protruding direction of the supply-side joint 634 are different in the first fixture 632A and the second fixture 632B. Since the discharger groove 632f and the supply groove 632g of the first fixture 632A are formed in two adjacent side surfaces, the discharger-side joint 633 and the supply-side joint 634 protrude from the two adjacent side surfaces. Since the discharger groove 632f and the supply groove 632g of the second fixture 632B are formed in two opposing side surfaces, the discharger-side joint 633 and the supply-side joint 634 protrude from the two opposing side surfaces.

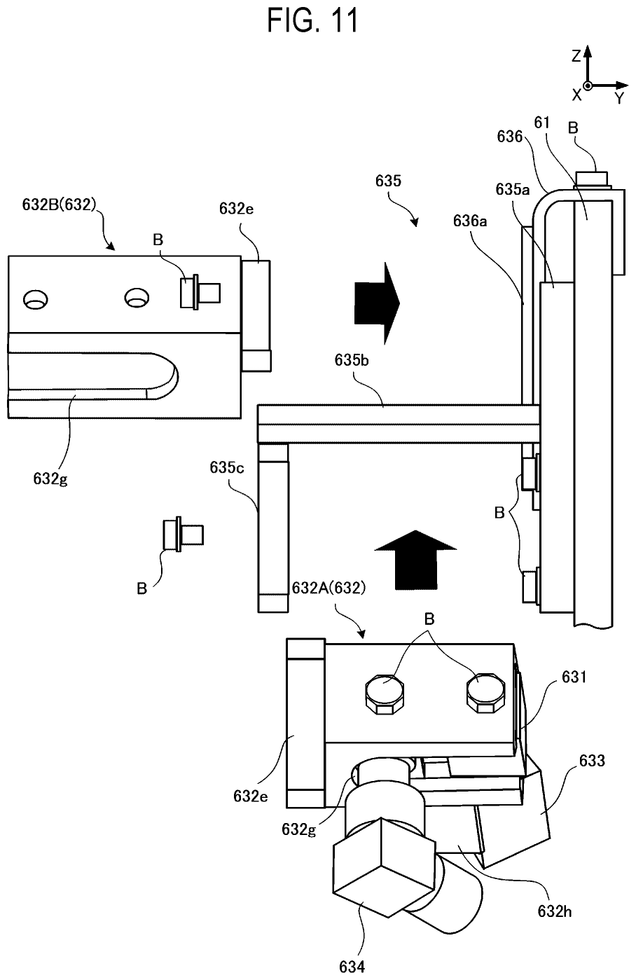

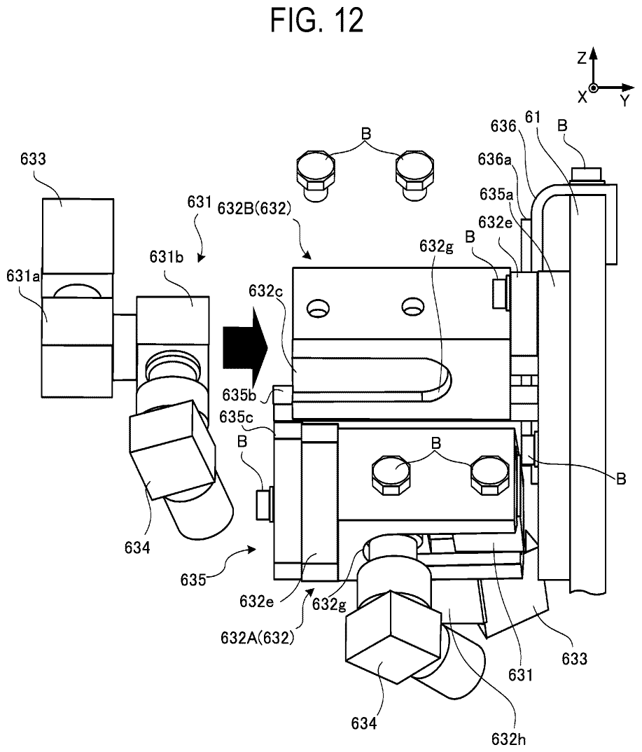

As shown in FIG. 4, the holder 635 fixes the support 63 to the cleaning apparatus 1. The holder 635 includes a main body plate 635a, an extension plate 635b, and a support plate 635c. The main body plate 635a is a plate fixed to the fixing plate 61 by fasteners B. As shown in FIG. 11, the attachment plate 632e of the second fixture 632B is fixed to the main body plate 635a by fasteners B. The extension plate 635b is a plate provided to extend vertically from the main body plate 635a (extend in the left-hand direction in FIG. 11). The support plate 635c is a plate fixed to an end portion of the extension plate 635b opposite to the main body plate 635a to face the main body plate 635a and be in parallel with the main body plate 635a. As shown in FIGS. 11 and 12, the attachment plate 632e of the first fixture 632A is fixed to the support plate 635c by fasteners B. The first fixture 632A and the second fixture 632B fixed to the holder 635 are in parallel with each other in a longitudinal direction, and the open ends thereof face opposite directions.

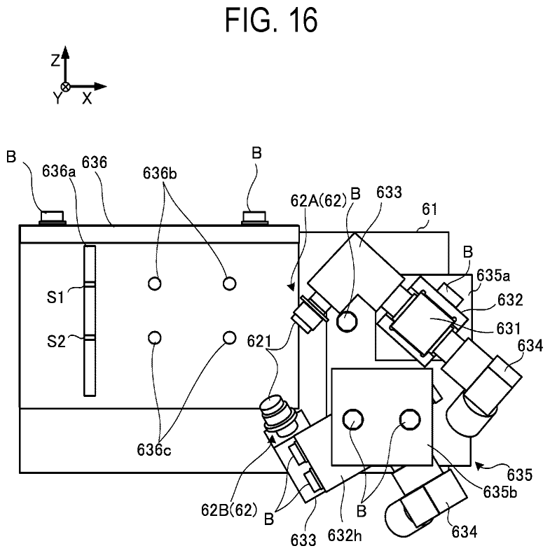

As shown in FIGS. 4 and 16, the base plate 636 is a plate fixed to the same surface of the fixing plate 61 to which the holder 635 is fixed. A scale member 636a for aligning the adjustment jig 70, which will be described later, is attached to the base plate 636. In addition, attachment holes 636b and 636c for attaching the adjustment jig 70 are formed in the base plate 636. The scale member 636a and the attachment holes 636b and 636c will be described together with the adjustment jig 70.

### <Support Column>

As shown in FIGS. 1, 3, and 15, the support column 64 extends vertically from the bottom 10a of the chamber 10 at a position adjacent to an end portion of the fixing plate 61.

### <Cover>

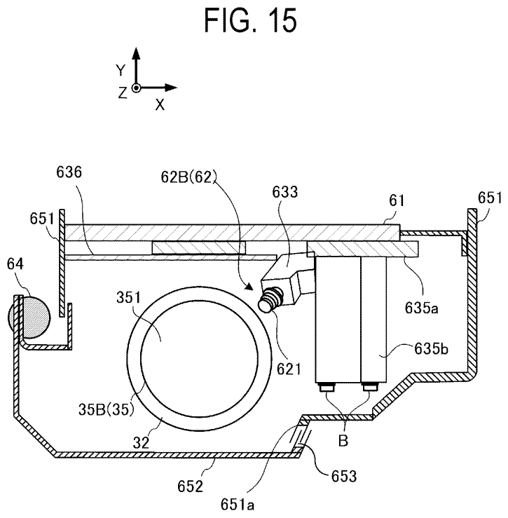

The cover 65 is interposed between the first brush 35A and the second brush 35B, which are located at the retracted position, and the substrate W to block scattering of the brush cleaning liquid CL to the substrate W. The cover 65 also covers the first discharger 62A and the second discharger 62B. As shown in the horizontal cross-sectional view of FIG. 15, the cover 65 is a plate that covers surroundings of the first brush 35A and the second brush 35B, and includes a fixed cover 651 and an openable cover 652. The fixed cover 651 is fixed to the fixing plate 61. The fixed cover 651 has an opening 651a through which the first brush 35A and the second brush 35B can pass.

The openable cover 652 is fixed to the support column 64, and opens and closes the opening 651a by rotating about the support column 64 as an axis. In addition, since the support column 64 is provided to be rotatable by a drive source such as a motor (not shown) or the like, the openable cover 652 rotates according to rotation of the support column 64. An end portion of the openable cover 652 and an end portion of the fixed cover 651 are not in contact with each other when the opening 651a is closed, and a curved ventilation path such as a labyrinth structure is formed between the end portion of the openable cover 652 and the end portion of the fixed cover 651. In addition, a lower side of the cover 65 is open, and the brush cleaning liquid CL flows down to a lower side of the chamber 10. Although not shown, upper portions of the fixed cover 651 and the openable cover 652 have notches at positions corresponding to the body 31 of the first brush 35A. As a result, when the openable cover 652 is closed, a surrounding of the body 31 is covered by the fixed cover 651 and the openable cover 652.

### Adjustment Jig

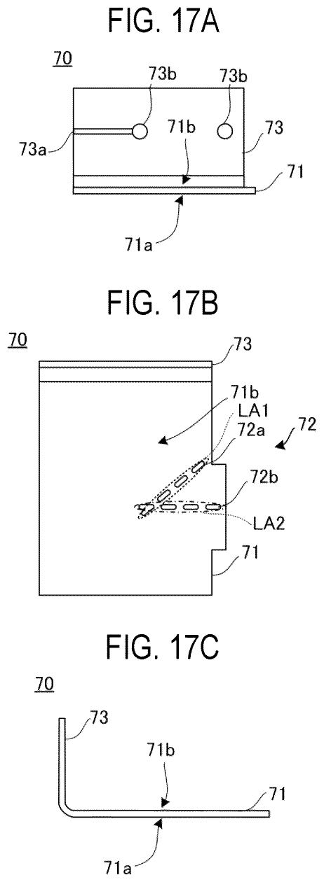

The adjustment jig 70 is a tool for adjusting positions of the first discharger 62A and the second discharger 62B in the cleaning apparatus 1. As shown in FIGS. 17A to 17C, the adjustment jig 70 includes a liquid landing plate 71, reference holes 72, and a fixer 73. The liquid landing plate 71 is a plate on which the brush cleaning liquids CL1 and CL2 discharged from the first discharger 62A and the second discharger 62B land at positions corresponding to the contact surfaces 351 of the first brush 35A and the second brush 35B at the retracted position. One surface of the liquid landing plate 71 is a first liquid landing surface 71a on which the brush cleaning liquid CL1 discharged from the first discharger 62A lands, and the other side is a second liquid landing surface 71b on which the brush cleaning liquid CL2 discharged from the second discharger 62B lands.

The reference holes 72 are a plurality of through-holes corresponds to the liquid landing areas LA1 and LA2 of the brush cleaning liquids CL1 and CL2 discharged from the first and second dischargers 62A and 62B, respectively, and is provided linearly in the liquid landing plate 71. In the present embodiment, the reference holes 72 provided for checking the liquid landing area LA1 of the first discharger 62A are referred to as first reference holes 72a, and the reference holes 72 provided for checking the liquid landing area LA2 of the second discharger 62B are referred to as second reference holes 72b.

The first reference holes 72a are configured by a plurality of (four in FIG. 17B) through-holes formed in a row in, for example, an elliptical region, which has a major axis in parallel to the linear liquid landing area LA1 (see FIG. 6A) and corresponds to the liquid landing area LA1. The second reference holes 72b are configured by a plurality of (four in FIG. 17B) through-holes formed in a row in, for example, an elliptical region, which has a major axis in parallel to the linear liquid landing area LA2 (see FIG. 6B) and corresponds to the liquid landing area LA2. Arrangement directions of the first reference holes 72a and the second reference holes 72b of the present embodiment have different angles in a plan view, but through-holes on respective one end sides are formed to be combined. Therefore, the through-holes on the respective one end sides have a shape obtained by synthesizing elliptical shapes at different angles. These one end sides correspond to the centers C of the contact surfaces 351.

The fixer 73 selectively fixes the liquid landing plate 71 to any of a position corresponding to the contact surface 351 of the first brush 35A and a position corresponding to the contact surface 351 of the second brush 35B (see FIGS. 18A and 18B). The fixer 73 is a plate obtained by bending one end side of the liquid landing plate 71 in a direction perpendicular to the liquid landing plate 71. The fixer 73 is provided with a reference mark 73a and attachment holes 73b. The reference mark 73a is a linear groove in parallel to the liquid landing plate 71. The attachment holes 73b are through-holes for fixing the fixer 73 to the base plate 636 by fasteners B.

On the other hand, as shown in FIG. 16, the scale member 636a provided on the base plate 636 of the cleaning apparatus 1 has a first scale S1 for positioning the liquid landing plate 71 at a position corresponding to the contact surface 351 of the first brush 35A and a second scale S2 for positioning the liquid landing plate 71 at a position corresponding to the contact surface 351 of the second brush 35B. The first scale S1 and the second scale S2 are grooves formed in the scale member 636a. Further, the attachment holes 636b provided in the base plate 636 are holes for positioning the liquid landing plate 71 at a position corresponding to the contact surface 351 of the first brush 35A. The attachment holes 636c are holes for positioning the liquid landing plate 71 at a position corresponding to the contact surface 351 of the second brush 35B.

By aligning the reference mark 73a of the fixer 73 with the first scale S1 and fastening fasteners B to the attachment holes 636b via the attachment holes 73b, as shown in FIG. 18A, the first liquid landing surface 71a of the liquid landing plate 71 can be set to a height position of the contact surface 351 of the first brush 35A located at the retracted position. By aligning the reference mark 73a of the fixer 73 with the second scale S2 and fastening the fasteners B to the attachment holes 636c via the attachment holes 73b, as shown in FIG. 18B, the second liquid landing surface 71b of the liquid landing plate 71 can be set to a height position of the contact surface 351 of the second brush 35B. The first brush 35A and the brush holder 32 in FIG. 18A are shown imaginarily by two-dot chain lines to explain the height position of the first liquid landing surface 71a (shown by a one-dot chain line). In addition, the second brush 35B and the brush holder 32 in FIG. 18B are shown imaginarily by two-dot chain lines to explain the height position of the second liquid landing surface 71b (shown by a one-dot chain line).

### Controller

As shown in FIG. 1, the controller 100 is a computer that controls individual components of the cleaning apparatus 1, and includes a memory configured to store various information and programs related to substrate cleaning and a processor configured to execute the various programs.

The controller 100 controls individual mechanisms by outputting operation commands to a drive circuit that drives the door opening/closing mechanisms for the load/unload port and the work port of the chamber 10, the rotation mechanism for the rollers 20a of the rotation driver 20, the drive mechanism for moving the first holder 21 and the second holder 22, the drive mechanism 42 of the brush driver 40, the supply mechanism of the cleaning liquid discharger 50, the liquid supply 624 for supplying the brush cleaning liquid CL to the discharger 62 of the brush cleaner 60, and the drive source for rotating the openable cover 652. In the present embodiment, the controller 100 is set so that the discharger 62 discharges the brush cleaning liquid CL only when the brush 35 is at the retracted position. In addition, the controller 100 may be set so that the discharger 62 discharges the brush cleaning liquid CL only when the openable cover 652 closes the opening 651a.

Although not shown, a display part and an input part are connected to the controller 100. The display is an output device such as a display, a lamp, a meter, or the like, by which information for checking a state of the cleaning apparatus 1 becomes visible to the operator. The input part is an input device such as a switch, a touch panel, a keyboard, a mouse, or the like, by which the operator operates the cleaning apparatus 1 via the controller 100 or inputs settings.

### Attachment of Discharger

A procedure for attaching the discharger 62 so that the discharger 62 is supported by the support 63 will be described. In addition, the holder 635 is attached to the fixing plate 61 by fixing the main body plate 635a to the fixing plate 61 with the fasteners B.

### Attachment of First Discharger

First, a procedure for attaching the first discharger 62A will be described. As shown in FIG. 9, the discharger-side joint 633 and the supply-side joint 634 are connected to the fixing joint 631. More specifically, the discharger-side joint 633 is connected to one side surface of the block 631a, and the supply-side joint 634 is connected to one side surface of the block 631b. Since these one side surfaces are parallel to the longitudinal direction of the fixing joint 631, the discharger-side joint 633 and the supply-side joint 634 protrude in a direction perpendicular to the longitudinal direction of the fixing joint 631.

At this time, angles of the blocks 631a and 631b can be changed by rotating them about an axis in the longitudinal direction of the fixing joint 631. In addition, angles of the discharger-side joint 633 and the supply-side joint 634 can be changed by rotating them about an axis in a direction perpendicular to the longitudinal direction of the fixing joint 631.

By inserting the fixing joint 631 into the insertion hole 632c of the first fixture 632A until the fixing joint 631 is brought into contact with the contact surface 632d and screw-inserting the fasteners B into the holes, the fixing joint 631 is fixed. At this time, the angles of the blocks 631a and 631b are adjusted, so that the connection portion with the discharger-side joint 633 enters the discharger groove 632f and the connection portion with the supply-side joint 634 enters the supply groove 632g. In addition, as shown in FIG. 10, the discharger-side joint 633 is rotated so that a side surface thereof is aligned with the inclined surface 632i of the angle determinator 632h.

As a result, since the four surfaces of the blocks 631a and 631b are brought into contact with the four surfaces of the insertion hole 632c, rotation of the fixing joint 631 about the axis thereof is restricted. Further, since the end portion of the fixing joint 631 is brought into contact with the contact surface 632d, the position in the insertion direction is determined. Furthermore, since the side surface of the discharger-side joint 633 is brought into contact with the inclined surface 632i of the angle determinator 632h, the angle of the discharger-side joint 633 is determined. Since the angle of the discharger-side joint 633 is determined, an axial angle of the first discharger 62A fixed to the discharger-side joint 633 is determined.

In addition, as shown in FIG. 11, the first fixture 632A is attached to the holder 635. That is, the first fixture 632A to which the fixing joint 631 is fixed as described above is inserted between the support plate 635c and the main body plate 635a, and the attachment plate 632e of the first fixture 632A is attached to the support plate 635c with the fasteners B.

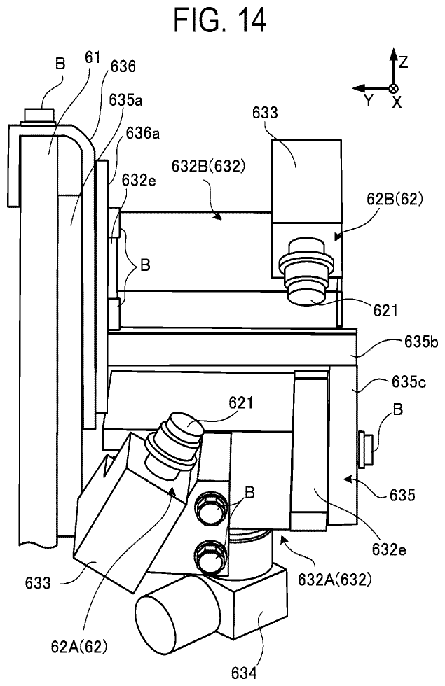

Here, the first discharger 62A is connected to the discharger-side joint 633 (see FIG. 14). That is, the nozzle tip 621 is screw-inserted into an end portion of the discharger-side joint 633. The first discharger 62A is fixed in a direction facing the first brush 35A located at the retracted position. Further, by adjusting the amount of screwing the nozzle tip 621, the extension direction of the liquid landing area LA1 formed by the brush cleaning liquid CL1 discharged from the elliptical discharge port 622 is set to a radial direction of the contact surface 351 of the first brush 35A.

As a result, as shown in FIGS. 3, 5A, and 5B, the first discharger 62A is positioned to discharge the brush cleaning liquid CL1 in an obliquely upward direction, which intersects with the direction in which the axis of the first brush 35A extends, from outside the first brush 35A and the second brush 35B located at the retracted position toward the first brush 35A. The fan-like plane of the brush cleaning liquid CL1 discharged from the first discharger 62A is perpendicular to the contact surface 351 of the first brush 35A. Further, as shown in FIG. 6A, the first discharger 62A is attached so that the liquid landing area LA1 of the brush cleaning liquid CL1 on the first brush 35A has a length that covers from the outer peripheral edge to the center C of the contact surface 351. For example, a position of one end of the liquid landing area LA1 is slightly beyond the center C of the contact surface 351, and a position of the other end thereof corresponds to a lower surface of the brush holder 32. Therefore, the brush cleaning liquid CL1 lands on an area equal to or larger than a radius of the contact surface 351 of the first brush 35A and on an entire side surface of the first brush 35A in the axial direction of the first brush 35A.

### Attachment of Second Discharger

Next, a procedure for attaching the second discharger 62B will be described. First, as shown in FIG. 11, the second fixture 632B is attached to the holder 635. That is, the second fixture 632B is attached to the main body plate 635a by the fasteners B so that the second fixture 632B is in parallel with the axis of the first fixture 632A.

Subsequently, the discharger-side joint 633 to which the second discharger 62B is attached and the supply-side joint 634 are connected to the fixing joint 631. This procedure is similar to that of the first discharger 62A described above.

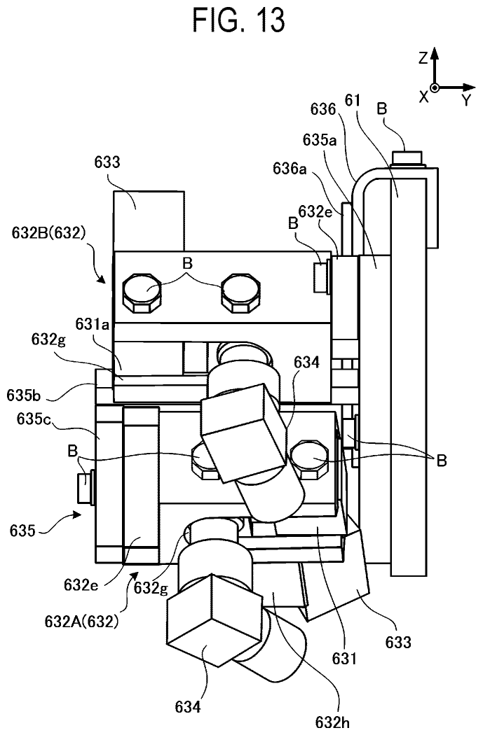

Then, as shown in FIGS. 12 and 13, the fixing joint 631 is inserted into the insertion hole 632c of the second fixture 632B until the fixing joint 631 is brought into contact with the contact surface 632d, and the fasteners B are screw-inserted into the holes to fix the fixing joint 631. At this time, the angles of the blocks 631a and 631b are adjusted so that the connection portion with the discharger-side joint 633 enters the discharger groove 632f and the connection portion with the supply-side joint 634 enters the supply groove 632g. Therefore, as described above, the rotation of the fixing joint 631 about the axis thereof is restricted and the position in the insertion direction is determined.

Here, as shown in FIG. 14, the second discharger 62B is connected to the discharger-side joint 633. That is, the nozzle tip 621 is screw-inserted into the end portion of the discharger-side joint 633. An axial direction of the second discharger 62B is set to be perpendicular to the axis of the fixing joint 631. As a result, the second discharger 62B is fixed in a direction facing the second brush 35B. Further, by adjusting the amount of screwing the nozzle tip 621, the extension direction of the liquid landing area LA2 formed by the brush cleaning liquid CL2 discharged from the elliptical discharge port 622 is set to be a radial direction of the contact surface 351 of the second brush 35B.

As a result, as shown in FIGS. 3, 5A, and 5B, the second discharger 62B is positioned to discharge the brush cleaning liquid CL2 in an obliquely downward direction, which intersects with the direction in which the axis of the second brush 35B extends, from outside the first brush 35A and the second brush 35B located at the retracted positions toward the second brush 35B. The fan-like plane of the brush cleaning liquid CL2 discharged from the second discharger 62B is perpendicular to the contact surface 351 of the second brush 35B. Further, as shown in FIG. 6B, the second discharger 62B is attached so that the liquid landing area LA2 of the brush cleaning liquid CL2 on the second brush 35B has a length that covers from the outer peripheral edge to the center C of the contact surface 351. For example, a position of one end of the liquid landing area LA2 is slightly beyond the center C of the contact surface 351, and a position of the other end thereof corresponds to an upper surface of the brush holder 32. Therefore, the brush cleaning liquid CL2 lands on an area equal to or larger than a radius of the contact surface 351 of the second brush 35B and on an entire side surface of the second brush 35B in the axial direction of the second brush 35B.

In addition, since the first discharger 62A is inclined by the inclined surface 632i of the angle determinator 632h, the brush cleaning liquid CL1, which is spread in a fan-like plane shape from the discharge port 622 of the first discharger 62A and lands linearly on the contact surface 351, lands on the liquid landing area LA1 having the length that covers from the outer peripheral edge to the center C of the contact surface 351 of the first brush 35A, without interfering with the brush cleaning liquid CL2 discharged from the discharge port 622 of the second discharger 62B and spread in a fan-like plane shape.

### Adjustment of Attachment Position

A method of adjusting positions of the first discharger 62A and the second discharger 62B attached as described above by using the adjustment jig 70 will be described.

### <Adjustment of First Discharger>

First, adjustment of the position of the first discharger 62A will be described. As shown in FIGS. 4 and 18A, the reference mark 73a of the fixer 73 of the adjustment jig 70 is aligned with the first scale S1, and the fasteners B are fastened to the attachment holes 636b via the attachment holes 73b. Thus, the liquid landing plate 71 is fixed to a position corresponding to the contact surface 351 of the first brush 35A located at the retracted position (first fixing process). That is, the first liquid landing surface 71a of the liquid landing plate 71 is set to be flush with the contact surface 351 of the first brush 35A.

Then, the brush cleaning liquid CL1 is discharged from the first discharger 62A so that the brush cleaning liquid CL1 lands on the liquid landing plate 71 (first liquid landing process). As a result, the brush cleaning liquid CL1 lands on the first liquid landing surface 71a. The operator adjusts the position of the first discharger 62A based on a passing state of the brush cleaning liquid CL1 through the reference holes 72 (first adjustment process).

That is, the operator checks whether the brush cleaning liquid CL1 passes through the four through-holes of the first reference holes 72a. When the brush cleaning liquid CL1 passes through the four through-holes, it can be determined that the position of the first discharger 62A is normal.

On the other hand, when there is at least one through-hole among the four through-holes through which the brush cleaning liquid CL1 has not passed, it can be determined that the position of the first discharger 62A is not normal. When it is determined that the position is not normal, the operator adjusts the position of the first discharger 62A. For example, the operator adjusts an angle of the linear liquid landing area LA1 by adjusting the amount of screwing the nozzle tip 621.

### <Adjustment of Second Discharger>

Next, adjustment of the position of the second discharger 62B will be described. As shown in FIGS. 4 and 18B, the reference mark 73a of the fixer 73 of the adjustment jig 70 is aligned with the second scale S2, and the fasteners B are fastened to the attachment holes 636c via the attachment holes 73b. Thus, the liquid landing plate 71 is fixed to a position corresponding to the contact surface 351 of the second brush 35B located at the retracted position (second fixing process). That is, the second liquid landing surface 71b of the liquid landing plate 71 is set to be flush with the contact surface 351 of the second brush 35B.

Then, the brush cleaning liquid CL2 is discharged from the second discharger 62B so that the brush cleaning liquid CL2 lands on the liquid landing plate 71 (second liquid landing process). As a result, the brush cleaning liquid CL2 lands on the second liquid landing surface 71b. The operator adjusts the position of the second discharger 62B based on a passing state of the brush cleaning liquid CL2 through the reference holes 72 (second adjustment process).

That is, the operator checks whether the brush cleaning liquid CL2 passes through the four through-holes of the second reference holes 72b. When the brush cleaning liquid CL2 passes through the four through-holes, it can be determined that the position of the second discharger 62B is normal.

On the other hand, when there is at least one through-hole among the four through-holes through which the brush cleaning liquid CL2 has not passed, it can be determined that the attachment position of the second discharger 62B is not normal. When it is determined that the attachment position of the second discharger 62B is not normal, the operator adjusts the position of the second discharger 62B. For example, an angle of the linear liquid landing area LA2 is adjusted by adjusting the amount of screwing the nozzle tip 621. Further, the angle of the second discharger 62B is adjusted by adjusting the angle of the discharger-side joint 633 with respect to the fixing joint 631.

After the attachment positions of the first discharger 62A and the second discharger 62B have been adjusted as described above, the adjustment jig 70 is removed from the base plate 636.

### Operations

Operations of the cleaning apparatus 1 configured as above will be described.

### Loading Substrate

First, an operation of loading the substrate W will be described. The transfer robot loads the substrate W transferred from the previous process into a location between the rollers 20a of the first holder 21 and the second holder 22 via the load/unload port of the cleaning apparatus 1. The first holder 21 and the second holder 22 move in directions approaching each other. Then, the four rollers 20a move toward the substrate W and are brought into contact with the outer periphery of the substrate W, thereby holding the substrate W. At this time, the upper and lower arms 41 are in a state retracted outside the substrate W so that the brushes 35 are located at the retracted position.

### Cleaning Front and Back Surfaces of Substrate

Next, a cleaning operation for the substrate W will be described. As shown in FIG. 2, as the rollers 20a rotate clockwise in the figure, the substrate W rotates counterclockwise.

The substrate cleaning liquid SL is discharged from the discharge port of the nozzle 51 of the cleaning liquid discharger 50. By a centrifugal force generated by the rotation of the substrate W, the substrate cleaning liquid SL supplied to the substrate W flows over the front and back surfaces of the substrate W and is scattered outward from the substrate W.

The upper and lower arms 41 (indicated by two-dot chain lines in FIG. 2) located at the retracted positions swing to above the outer periphery of the substrate W while rotating the brushes 35 by the motor, and then stop temporarily. Then, the upper and lower arms 41 move toward the substrate W, so that the brushes 35 of the upper and lower substrate cleaners 30 are brought into contact with the front and back surfaces of the substrate W.

Then, as the upper and lower arms 41 swing, the upper and lower brushes 35 move horizontally while being in contact with the substrate W. At this time, since the substrate cleaning liquid SL is discharged from the discharge port of the nozzle 51, the substrate cleaning liquid SL flows between the brushes 35 and the substrate W. That is, the brushes 35, which start moving from one side of the outer periphery of the substrate W, move along the arc trajectory to push out contaminants together with the substrate cleaning liquid SL to the outer periphery of the substrate W.

As shown in FIG. 2, the brushes 35 move while passing a vicinity of the center of the substrate W. Thereafter, when the brushes 35 pass the other side of the outer periphery of the substrate W and move away from the substrate W, the cleaning process for the substrate W by the brushes 35 ends.

Then, as the upper and lower arms 41 move in directions separating from each other, the upper and lower brushes 35 are separated from each other, and the arms 41 swing to retract to the retracted position outside the outer periphery of the substrate W. Thereafter, by repeating the above-described operation, cleaning with the brushes 35 may be performed a plurality of times.

The cleaning liquid discharger 50 continues to discharge the substrate cleaning liquid SL for a predetermined period of time even after the brushes 35 get out of the substrate W. Thus, a rinsing process is performed on the substrate W. That is, the rinsing process is started with the movement of the brushes 35 to the retracted position, and cleaning the brushes 35, which will be described later, is performed in parallel with the rinsing process. When a predetermined period of time has elapsed after the start of the rinsing process, the discharge of the substrate cleaning liquid SL is stopped to terminate the rinsing process, and the cleaning process for the substrate W ends. When the cleaning process for the substrate W ends, the first holder 21 and the second holder 22 move in directions separating from each other and the substrate W is released. The transfer robot unloads the released substrate W via the load/unload port of the cleaning apparatus 1. In addition, the rinsing process may be performed by supplying a liquid other than the substrate cleaning liquid SL to the substrate W.

### Cleaning Brush

An operation of cleaning the brushes 35 will be described. First, the arm 41 is swung to move the brushes 35, which has been used to clean the substrate W, to the retracted position. At this time, the openable cover 652 is open, and the brushes 35 enter the cover 65 via the opening 651a of the fixed cover 651. Then, the openable cover 652 is closed to cover the brushes 35.

Subsequently, the first arm 41A and the second arm 41B move vertically, so that the position of the contact surface 351 of the first brush 35A becomes the position of the first liquid landing surface 71a when the adjustment jig 70 is attached, and the position of the contact surface 351 of the second brush 35B becomes the position of the second liquid landing surface 71b when the adjustment jig 70 is attached. Further, a rotation speed (the number of rotations per unit time) of the brushes 35 is set to be lower than a rotation speed thereof when the substrate W is being cleaned.

In this state, the first discharger 62A and the second discharger 62B discharge the brush cleaning liquids CL1 and CL2 to the first brush 35A and the second brush 35B which are rotating at the low rotation speed. At this time, as shown in FIG. 5B, the brush cleaning liquid CL1 discharged by the first discharger 62A is spread in a fan-like plane shape, and as shown in FIG. 6A, the brush cleaning liquid CL1 reaches the contact surface 351 to form the linear liquid landing area LA1. Further, as shown in FIG. 5A, the brush cleaning liquid CL2 discharged by the second discharger 62B is spread in a fan-like plane shape, and as shown in FIG. 6B, the brush cleaning liquid CL2 reaches the contact surface 351 to form the linear liquid landing area LA2. The brush cleaning liquid CL1 discharged from the first discharger 62A and the brush cleaning liquid CL2 discharged from the second discharger do not collide with each other before the landing. That is, a portion where the brush cleaning liquids CL1 and CL2 interfere with each other and are hindered from landing is not generated. Furthermore, since the rotation speed of the brushes 35 is set to be lower than the rotation speed thereof when cleaning the substrate W, a water pressure by the brush cleaning liquid CL can be increased in the liquid landing area LA. Since the water pressure is high, particles adhering to the brushes 35 are pushed out easily, and it is possible to clean the brushes 35 more cleanly.

### Effects

(1) The cleaning apparatus 1 of the present embodiment as described above includes: the substrate cleaner 30 configured to clean the first surface and the second surface of the substrate W, which is being held and rotated, by bringing the circular contact surface 351 of the rotating first brush 35A into contact with the first surface of the rotating substrate W while supplying the substrate cleaning liquid SL to the first surface of the rotating substrate W, and by bringing the circular contact surface 351 of the rotating second brush 35B into contact with the second surface of the rotating substrate W while supplying the substrate cleaning liquid SL to the second surface of the rotating substrate W; and the brush cleaner 60 configured to clean the first brush 35A and the second brush 35B by discharging the brush cleaning liquids CL1 and CL2 from the discharger 62 to the contact surface 351 of the first brush 35A and the contact surface 351 of the second brush 35B, in a state in which the first brush 35A and the second brush 35B are located at the retracted position spaced apart from the substrate W. The discharger 62 includes the first discharger 62A configured to discharge the brush cleaning liquid CL1 so that the brush cleaning liquid CL1 lands linearly on the contact surface 351 of the first brush 35A; and the second discharger 62B configured to discharge the brush cleaning liquid CL2 so that the brush cleaning liquid CL2 lands linearly on the contact surface 351 of the second brush 35B. The brush cleaner 60 includes the support 63 configured to support the first discharger 62A and the second discharger 62B, so that the brush cleaning liquids CL1 and CL1 discharged from the first discharger 62A and the second discharger 62B do not interfere with each other until the brush cleaning liquids CL1 and CL2 land on the contact surface 351 of the first brush 35A and the contact surface 351 of the second brush 35B.

With this configuration, since the brush cleaning liquid CL1 discharged by the first discharger 62A and the brush cleaning liquid CL2 discharged by the second discharger 62B do not collide with each other, the brush cleaning liquid CL is not scattered before reaching the contact surface 351, and the brush cleaning liquids CL1 and CL2 can be efficiently supplied to the first brush 35A and the second brush 35B, respectively, to clean the first brush 35A and the second brush 35B. Thus, it is possible to maintain a degree of cleanliness of the first brush 35A and the second brush 35B and improve a quality of the substrate W. Further, since scattering of the brush cleaning liquid CL due to collision does not occur, it is possible to suppress adhesion of the brush cleaning liquid CL to the substrate W and improve the quality of the substrate W. Furthermore, even after the substrate W is unloaded, it is possible to prevent the brush cleaning liquid CL from being scattered and adhering to components in the cleaning chamber 11, particularly the rollers 20a. Thus, adhesion of the brush cleaning liquid CL to a next loaded substrate W via the rollers 20a can be suppressed, and it is possible to improve the quality of the substrate W.
(2) The support 63 supports the first discharger 62A and the second discharger 62B so that an extension direction of the linear liquid landing area LA1, on which the brush cleaning liquid CL1 lands, in the contact surface 351 of the first brush 35A is different from an extension direction of the linear liquid landing area LA2, on which the brush cleaning liquid CL2 lands, in the contact surface 351 of the second brush 35B. With this configuration, the brush cleaning liquid CL1 discharged by the first discharger 62A can reach the contact surface 351 of the first brush 35A without colliding with the brush cleaning liquid CL2 discharged by the second discharger 62B. In addition, the brush cleaning liquid CL2 discharged by the second discharger 62B can reach the contact surface 351 of the second brush 35B without colliding with the brush cleaning liquid CL1 discharged by the first discharger 62A.
(3) The linear liquid landing area LA, on which the brush cleaning liquid CL discharged from the discharger 62 lands, in each of the contact surfaces 351 has a length that covers from the outer peripheral edge to the center C of each of the contact surface 351. With this configuration, since the brush cleaning liquid CL hits a region exceeding a radius of the rotating brush 35, the entire rotating contact surface 351 can be cleaned with the brush cleaning liquid CL being in contact with the entire rotating contact surface 351. Since it is not necessary to expand the liquid landing area LA to a diameter of the brush 35, it is possible to suppress scattering of the brush cleaning liquid CL due to diffusion thereof.
(4) A discharge direction of the discharger 62 is set so that a plane, over which the brush cleaning liquid CL discharged from the discharger 62 is spread until the brush cleaning liquid CL lands on each of the contact surface 351, is perpendicular to each of the contact surface 351. With this configuration, the brush cleaning liquid CL can hit the contact surface 351 strongly, thereby improving cleaning ability.
(5) The first brush 35A and the second brush 35B are provided to be swingable via the first arm 41A and the second arm 41B, respectively, and the first discharger 62A and the second discharger 62B are disposed in a region between the first arm 41A and the second arm 41B when the first brush 35A and the second brush 35B are located at the retracted position.

With this configuration, since the first discharger 62A and the second discharger 62B are accommodated between the first arm 41A and the second arm 41B, it is possible to reduce a space in a plan view and to suppress an increase in size of the apparatus.
(6) The support 63 includes: the prismatic columnar fixing joint 631 configured to support the discharger 62 and having an internal flow path for supplying the brush cleaning liquid CL to the discharger 62; and the fixture 632 including the insertion hole 632c into which the fixing joint 631 is inserted, the insertion hole 632c having a plurality of surfaces brought into contact with a plurality of side surfaces of the fixing joint 631 and being configured to fix an angle of the fixing joint 631.

With this configuration, by inserting the fixing joint 631 into the insertion hole 632c of the fixture 632, it is possible to perform positioning of the discharger 62.
(7) The portion of the fixing joint 631 inserted into the insertion hole 632c includes a rectangular parallelepiped block. With this configuration, positioning of the discharger 62 can be performed by the fixing joint 631 with a simple shape.
(8) The support 63 further includes the discharger-side joint 633 having an internal flow path for supplying the brush cleaning liquid CL to the discharger 62 and connected to the fixing joint 631 so that an angle of the discharger 62 becomes changeable, and the fixture 632 further includes the angle determinator 632h configured to be in contact with the discharger-side joint 633 to determine the angle of the discharger 62.

With this configuration, the angle of the discharger 62 can be determined easily by inserting the fixing joint 631 into the fixture 632 and bringing the discharger-side joint 633 into contact with the angle determinator 632h.
(9) The insertion hole 632c has the contact surface 632d with which an end portion of the inserted fixing joint 631 is in contact to determine a position of the fixing joint 631 in the insertion direction. With this configuration, when the fixing joint 631 is inserted until the fixing joint 631 is brought into contact with the contact surface 632d, the position of the discharger 62 in the insertion direction can be determined easily.
(10) The cleaning apparatus 1 further includes the supply-side joint 634 connected to the fixing joint 631, having an internal flow path for supplying the brush cleaning liquid CL to the discharger 62, and connected to the pipe 624a for supplying the brush cleaning liquid CL, wherein the discharger 62 and the supply-side joint 634 are provided at positions spaced apart from each other in the insertion direction of the fixing joint 631 into the fixture 632.

With this configuration, since the discharger 62 and the supply-side joint 634 can deviate from each other in a horizontal direction, it is possible to suppress an increase of a space in a vertical direction.
(11) The brush cleaner 60 further includes the cover 65 interposed between the first brush 35A and the second brush 35B, which are located at the retracted position, and the substrate cleaner 30, and configured to block the brush cleaning liquid CL from being scattered to the substrate W. With this configuration, it is possible to prevent the brush cleaning liquid CL from adhering to the substrate W during brush cleaning.
(12) The cover 65 includes: the fixed cover 651 having the opening 651a that allows the first brush 35A and the second brush 35B to pass through the opening 651a; and the openable cover 652 configured to open and close the opening 651a. With this configuration, it is possible to move the first brush 35A and the second brush 35B into and out of the cover 65 and to prevent the brush cleaning liquid CL from being scattered to the substrate W during brush cleaning.
(13) A bent path 653 is formed between the openable cover 652 that closes the opening 651a and the fixed cover 651. With this configuration, it is possible to prevent the brush cleaning liquid CL from leaking from a location between the openable cover 652 and the fixed cover 651 and adhering to the substrate W.
(14) The adjustment jig 70 according to the present embodiment, which is used for adjusting positions of the first discharger 62A and the second discharger 62B of the cleaning apparatus 1, includes: the liquid landing plate 71 on which the brush cleaning liquids CL1 and CL2 discharged from the first discharger 62A and the second discharger 62B land at positions corresponding to the contact surfaces 351 of the first brush 35A and the second brush 35B; the reference holes 72, which are a plurality of through-holes provided linearly and correspond to the liquid landing areas LA1 and LA2, on which the brush cleaning liquids CL1 and CL2 discharged from the first discharger 62A and the second discharger 62B land, respectively, in the liquid landing plate 71; and the fixer 73 configured to selectively fix the liquid landing plate 71 to any of a position corresponding to the contact surface 351 of the first brush 35A and a position corresponding to the contact surface 351 of the second brush 35B.

The adjustment method of adjusting positions of the first discharger 62A and the second discharger 62B of the cleaning apparatus 1 by using the adjustment jig 70 includes: the first fixing process of fixing the liquid landing plate 71 at a position corresponding to the contact surface 351 of the first brush 35A; after the first fixing process, the first liquid landing process of discharging the brush cleaning liquid CL1 from the first discharger 62A so that the brush cleaning liquid CL1 lands on the liquid landing plate 71; the first adjustment process of adjusting the position of the first discharger 62A based on a passing state of the brush cleaning liquid CL1 through the reference holes 72 in the first liquid landing process; the second fixing process of fixing the liquid landing plate 71 at a position corresponding to the contact surface 351 of the second brush 35B; after the second fixing process, the second liquid landing process of discharging the brush cleaning liquid CL2 from the second discharger 62B so that the brush cleaning liquid CL2 lands on the liquid landing plate 71; and the second adjustment process of adjusting the position of the second discharger 62B based on a passing state of the brush cleaning liquid CL2 through the reference holes 72 in the second liquid landing process.

With this configuration, it is possible to check in advance a liquid landing state on the contact surface 351 of the first brush 35A and a liquid landing state on the contact surface 351 of the second brush 35B and to adjust the positions of the first discharger 62A and the second discharger 62B.
(15) The cleaning apparatus 1 includes the first scale S1 configured to locate the liquid landing plate 71 at a position corresponding to the contact surface 351 of the first brush 35A, and the second scale S2 configured to locate the liquid landing plate 71 at a position corresponding to the contact surface 351 of the second brush 35B, and the fixer 73 has the reference mark 73a configured to be aligned with the first scale S1 to locate the liquid landing plate 71 at the position corresponding to the contact surface 351 of the first brush 35A, and configured to be aligned with the second scale S2 to locate the liquid landing plate 71 at the position corresponding to the contact surface 351 of the second brush 35B.

With this configuration, by aligning the reference mark 73a with the first scale S1 or the second scale S2, the position of the liquid landing plate 71 can be determined easily and accurately.

### Modifications

The present embodiment is not limited to the above-described aspects, and the following modifications can be also made.
(1) In the above-described embodiment, the first discharger 62A is disposed on the lower side and the second discharger 62B is disposed on the upper side. However, the first discharger 62A may be disposed on the upper side and the second discharger 62B may be disposed on the lower side. In addition, the angle determinator 632h may be provided in the second discharger 62B.
(2) The retracted position where the brush 35 is cleaned may be any location outside the region where the substrate W is held. Thus, the position to which the brush 35 is retracted may be provided separately from the brush cleaning position.
(3) A flow rate of the brush cleaning liquid CL1 discharged from the first discharger 62A and a flow rate of the brush cleaning liquid CL2 discharged from the second discharger 62B may be the same or different from each other.
(4) The number of the reference holes 72 is not limited to four, but may be any plural number.
(5) The first scale S1, the second scale S2, and the reference mark 73a may be grooves formed in members, or may be ones attached or printed on members, as long as they are visible to the operator.
(6) The brush cleaning liquid CL is not limited to pure water. For example, various liquids such as those exemplified as the substrate cleaning liquid SL may be used. In addition, multiple types of liquids may be switched and supplied to the brush 35.
(7) A two-fluid nozzle may be used for the discharger 62. For example, a nozzle that discharges a mixture of N₂ gas and pure water may be used.
(8) The cleaning apparatus 1 may be an apparatus that cleans only one surface of the substrate W, without including the second brush 35B. That is, the cleaning apparatus 1 may include: the substrate cleaner 30 configured to clean one surface of the substrate W, which is being held and rotated, by bringing the circular contact surface 351 of the rotating brush 35 into contact with the one surface of the rotating substrate W while supplying the substrate cleaning liquid SL to the one surface of the rotating substrate W; the brush cleaner 60 configured to clean the brush 35 by discharging the brush cleaning liquid CL from the discharger 62 to the contact surface 351, in a state in which the brush 35 is located at a retracted position spaced apart from the substrate W; and the support 63 configured to support the discharger 62.

In this case, all of the configurations illustrated in the above-described aspect are applicable except for the absence of the second brush 35B and the second discharger 62B. For example, the support 63 may include: the prismatic columnar fixing joint 631 configured to support the discharger 62 and having an internal flow path for supplying the brush cleaning liquid CL to the discharger 62; and the fixture 632 including the insertion hole 632c into which the fixing joint 631 is inserted, the insertion hole 632c having a plurality of surfaces brought into contact with a plurality of side surfaces of the fixing joint 631 and being configured to fix an angle of the fixing joint 631.

### Other Embodiments

The embodiments of the present disclosure and the modifications of individual components have been described above. However, the embodiments of the present disclosure and the modifications of individual components are presented as examples and are not intended to limit the scope of the present disclosure. These novel embodiments described above can be implemented in various other forms, and various omissions, substitutions, and modifications can be made without departing from the gist of the present disclosure. These embodiments and their modifications are included in the scope and gist of the present disclosure, and are included in the present disclosure described in the claims.

According to the present disclosure in some embodiments, it is possible to maintain a degree of cleanliness of a brush for cleaning a substrate and to improve a quality of the substrate.

While certain embodiments have been described, these embodiments have been presented by way of example only, and are not intended to limit the scope of the disclosures. Indeed, the embodiments described herein may be embodied in a variety of other forms. Furthermore, various omissions, substitutions, and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A cleaning apparatus comprising:
a substrate cleaner configured to clean a first surface and a second surface of a substrate, which is being held and rotated, by bringing a circular contact surface of a rotating first brush into contact with the first surface of the rotating substrate while supplying a substrate cleaning liquid to the first surface of the rotating substrate, and by bringing a circular contact surface of a rotating second brush into contact with the second surface of the rotating substrate while supplying the substrate cleaning liquid to the second surface of the rotating substrate; and
a brush cleaner configured to clean the first brush and the second brush by discharging a brush cleaning liquid from a discharger to the contact surface of the first brush and the contact surface of the second brush, in a state in which the first brush and the second brush are located at a retracted position spaced apart from a region where the substrate is held,
wherein the discharger includes:
a first discharger configured to discharge the brush cleaning liquid so that the brush cleaning liquid lands linearly on the contact surface of the first brush; and
a second discharger configured to discharge the brush cleaning liquid so that the brush cleaning liquid lands linearly on the contact surface of the second brush, and
wherein the brush cleaner includes a support configured to support the first discharger and the second discharger, so that the brush cleaning liquid discharged from the first discharger and the brush cleaning liquid discharged from the second discharger do not interfere with each other until the brush cleaning liquid lands on the contact surface of the first brush and the contact surface of the second brush.

2. The cleaning apparatus of claim 1, wherein the support supports the first discharger and the second discharger so that an extension direction of a linear liquid landing area, on which the brush cleaning liquid lands, in the contact surface of the first brush is different from an extension direction of a linear liquid landing area, on which the brush cleaning liquid lands, in the contact surface of the second brush.

3. The cleaning apparatus of claim 1, wherein a linear liquid landing area, on which the brush cleaning liquid discharged from the discharger lands, in each of the contact surfaces has a length that covers from an outer peripheral edge to a center of each of the contact surfaces.

4. The cleaning apparatus of claim 1, wherein a discharge direction of the discharger is set so that a plane, over which the brush cleaning liquid discharged from the discharger is spread until the brush cleaning liquid lands on each of the contact surfaces, is perpendicular to each of the contact surfaces.

5. The cleaning apparatus of claim 1, wherein the first brush and the second brush are provided to be swingable via a first arm and a second arm, respectively, and wherein the first discharger and the second discharger are disposed in a region between the first arm and the second arm when the first brush and the second brush are located at the retracted position.

6. The cleaning apparatus of claim 1, wherein the support includes:
a prismatic columnar fixing joint configured to support the discharger and having an internal flow path for supplying the brush cleaning liquid to the discharger; and
a fixture including an insertion hole into which the fixing joint is inserted, the insertion hole having a plurality of surfaces brought into contact with a plurality of side surfaces of the fixing joint and being configured to fix an angle of the fixing joint.

7. The cleaning apparatus of claim 6, wherein a portion of the fixing joint inserted into the insertion hole includes a rectangular parallelepiped block.

8. The cleaning apparatus of claim 6, wherein the support further includes a discharger-side joint having an internal flow path for supplying the brush cleaning liquid to the discharger, and connected to the fixing joint so that an angle of the discharger becomes changeable, and
wherein the fixture further includes an angle determinator configured to be in contact with the discharger-side joint to determine the angle of the discharger.

9. The cleaning apparatus of claim 6, wherein the insertion hole has a contact surface with which an end portion of the inserted fixing joint is in contact to determine a position of the fixing joint in an insertion direction.

10. The cleaning apparatus of claim 6, further comprising a supply-side joint connected to the fixing joint, having an internal flow path for supplying the brush cleaning liquid to the discharger, and connected to a pipe for supplying the brush cleaning liquid,
wherein the discharger and the supply-side joint are provided at positions spaced apart from each other in an insertion direction of the fixing joint into the fixture.

11. The cleaning apparatus of claim 1, wherein the brush cleaner further includes a cover interposed between the first brush and the second brush, which are located at the retracted position, and the substrate cleaner, and configured to block the brush cleaning liquid from being scattered to the substrate.

12. The cleaning apparatus of claim 11, wherein the cover includes:
a fixed cover having an opening that allows the first brush and the second brush to pass through the opening; and
an openable cover configured to open and close the opening.

13. The cleaning apparatus of claim 12, wherein a bent path is formed between the openable cover that closes the opening and the fixed cover.

14. A cleaning apparatus comprising:
a substrate cleaner configured to clean one surface of a substrate, which is being held and rotated, by bringing a circular contact surface of a rotating brush into contact with the one surface of the rotating substrate while supplying a substrate cleaning liquid to the one surface of the rotating substrate;
a brush cleaner configured to clean the brush by discharging a brush cleaning liquid from a discharger to the contact surface, in a state in which the brush is located at a retracted position spaced apart from a region where the substrate is held; and
a support configured to support the discharger,
wherein the support includes:
a prismatic columnar fixing joint configured to support the discharger and having an internal flow path for supplying the brush cleaning liquid to the discharger; and
a fixture including an insertion hole into which the fixing joint is inserted, the insertion hole having a plurality of surfaces brought into contact with a plurality of side surfaces of the fixing joint and being configured to fix an angle of the fixing joint.

15. An adjustment jig for adjusting positions of the first discharger and the second discharger of the cleaning apparatus of claim 1, comprising:
a liquid landing plate on which the brush cleaning liquid discharged from the first discharger and the second discharger lands at positions corresponding to the contact surfaces of the first brush and the second brush;
reference holes, which are a plurality of through-holes provided linearly and correspond to liquid landing areas, on which the brush cleaning liquid discharged from the first discharger and the brush cleaning liquid discharged from the second discharger land, respectively, in the liquid landing plate; and
a fixer configured to selectively fix the liquid landing plate to any of a position corresponding to the contact surface of the first brush and a position corresponding to the contact surface of the second brush.

16. The adjustment jig of claim 15, wherein the cleaning apparatus includes a first scale configured to locate the liquid landing plate at a position corresponding to the contact surface of the first brush, and a second scale configured to locate the liquid landing plate at a position corresponding to the contact surface of the second brush, and
wherein the fixer has a reference mark configured to be aligned with the first scale to locate the liquid landing plate at the position corresponding to the contact surface of the first brush, and configured to be aligned with the second scale to locate the liquid landing plate at the position corresponding to the contact surface of the second brush.

17. An adjustment method of adjusting positions of the first discharger and the second discharger of the cleaning apparatus by using the adjustment jig of claim 15, comprising:
a first fixing process of fixing the liquid landing plate at a position corresponding to the contact surface of the first brush;
after the first fixing process, a first liquid landing process of discharging the brush cleaning liquid from the first discharger so that the brush cleaning liquid lands on the liquid landing plate;
a first adjustment process of adjusting the position of the first discharger based on a passing state of the brush cleaning liquid through the reference holes in the first liquid landing process;
a second fixing process of fixing the liquid landing plate at a position corresponding to the contact surface of the second brush;
after the second fixing process, a second liquid landing process of discharging the brush cleaning liquid from the second discharger so that the brush cleaning liquid lands on the liquid landing plate; and
a second adjustment process of adjusting the position of the second discharger based on a passing state of the brush cleaning liquid through the reference holes in the second liquid landing process.
